(19) United States
(12) Patent Application Publication
(10) Pub. No.: US 2026/0332156 A1
(43) Pub. Date: Oct. 22, 2026

(54) ANALOG-TO-DIGITAL CONVERTER FOR PARTIAL DISCHARGE ULTRASONIC DETECTION

(71) Applicant: GUANGZHOU POWER SUPPLY BUREAU OF GUANGDONG POWER GRID CO., LTD, Guangzhou, Guangdong (CN)

(72) Inventors: Yong WANG, Guangzhou, Guangdong (CN); Jun XIONG, Guangzhou, Guangdong (CN); Lingming KONG, Guangzhou, Guangdong (CN); Jun CHEN, Guangzhou, Guangdong (CN); Mianzhi CHEN, Guangzhou, Guangdong (CN); Yilong CHEN, Guangzhou, Guangdong (CN)

(73) Assignee: GUANGZHOU POWER SUPPLY BUREAU OF GUANGDONG POWER GRID CO., LTD, Guangzhou, Guangdong (CN)

(21) Appl. No.: 18/994,162

(22) PCT Filed: Nov. 3, 2023
(86) PCT No.: PCT/CN2023/129572

§ 371 Date: Jan. 14, 2025

(30) Foreign Application Priority Data
Jul. 31, 2023 (CN) 202310949163.3

(51) Int. Cl. H03M 1/12; H03K 17/687

(52) U.S. Cl. CPC H03M 1/124; H03K 17/6871

(57) ABSTRACT

An analog-to-digital converter for partial discharge ultrasonic detection includes a bootstrapped switch, a sampling capacitor array, a comparator and an algorithmic logic controller. The bootstrapped switch is connected to an input end of the comparator and is turned on by using bootstrapping in response to a sampling clock signal, and is configured to receive an input signal. The sampling capacitor array is connected to the input end of the comparator and is configured to cache the input signal. The comparator is connected to the algorithmic logic controller, and is configured to compare the input signal with a reference signal bit by bit, generate and transmit a unit digital signal to the algorithmic logic controller. The algorithmic logic controller is configured to trigger an associated register bit by bit in response to the unit digital signal, generate and output a target digital signal.

This application claims priority to Chinese Patent Application No. 202310949163.3 titled “ANALOG-TO-DIGITAL CONVERTER FOR PARTIAL DISCHARGE ULTRASONIC DETECTION”, filed on Jul. 31, 2023, with the China National Intellectual Property Administration, which is incorporated herein by reference in its entirety.

### FIELD

The present disclosure relates to the technical field of analog-to-digital conversion, and in particular to an analog-to-digital converter for partial discharge ultrasonic detection.

### BACKGROUND

Normal production and life of people depend on a smooth and stable operation of a power grid system. The power grid system is complex and huge and is provided with a variety of devices. The device in the power grid may malfunction during the operation. A malfunction of the power grid may be resulted from an extreme weather, various emergencies, or an aging problem caused by a long-term operation of the devices in the power grid, affecting the normal production and life of people.

Insulation deterioration of a power device in a substation may cause partial discharge. Monitoring and locating the partial discharge is efficient means for an early warning of insulation fault of the device. A partial discharge signal is an analog signal, and fails to be directly processed by a computer or other electronic devices. The partial discharge signal is converted into a digital signal first, and then the digital signal is processed and subjected to feature extraction by the computer or other electronic device, to determine whether the power device malfunctions. In this case, the analog signal is converted into the digital signal by using an analog-to-digital converter.

The conventional analog-to-digital converter may be classified as a flash ADC, a pipeline ADC, a Σ-Δ ADC and a successive approximation ADC (SARADC) according to architectures. These analog-to-digital converters are significantly different in operation principle and operation performance, and thus are applied to different scenarios based on respective characteristics. However, the conventional ADC has large power consumption and high cost in a detection process of the partial discharge signal in the power device.

### SUMMARY

A low-power analog-to-digital converter for partial discharge detection is provided according to the present disclosure, to solve the problem that the conventional ADC has large power consumption and high cost in the detection process of the partial discharge signal in the power device.

An analog-to-digital converter for partial discharge ultrasonic detection according to the present disclosure, includes a bootstrapped switch, a sampling capacitor array, a comparator and an algorithmic logic controller. The bootstrapped switch is connected to an input end of the comparator and is turned on by using bootstrapping in response to a received sampling clock signal, and is configured to receive an input signal to be cached in the sampling capacitor array. The sampling capacitor array is connected to the input end of the comparator, and is configured to cache the input signal. An output end of the comparator is connected to the algorithmic logic controller, and the comparator is configured to compare the input signal with a reference signal bit by bit, generate a unit digital signal and transmit the unit digital signal to the algorithmic logic controller. The algorithmic logic controller is configured to trigger an associated register bit by bit in response to the unit digital signal, generate a target digital signal and output the target digital signal.

In an embodiment, the bootstrapped switch includes a third MOS transistor, a fourth MOS transistor, a fifth MOS transistor, a sixth MOS transistor, a seventh MOS transistor, an eighth MOS transistor, a ninth MOS transistor, a tenth MOS transistor and a digital power supply. In response to the received sampling clock signal at a low level, the bootstrapped switch is configured to turn on the third MOS transistor and the eighth MOS transistor, gates of the fourth MOS transistor, the sixth MOS transistor, the ninth MOS transistor and the tenth MOS transistor are grounded through the seventh MOS transistor and the eighth MOS transistor, where the fourth MOS transistor is turned on, and the sixth MOS transistor, the ninth MOS transistor and the tenth MOS transistor are turned off, pre-charging to the digital power supply. In response to the received sampling clock signal at a high level, the fourth MOS transistor and the third MOS transistor are turned off, the fifth MOS transistor is turned on, and the bootstrapped switch is turned on to receive the input signal to be cached in the sampling capacitor array.

In an embodiment, the comparator is a double-tail current dynamic latch comparator.

In an embodiment, the comparator is configured to compare the input signal with the reference signal bit by bit; generate a unit digital signal with a value of 0 and transmit the unit digital signal to the algorithmic logic controller if the input signal is less than the reference signal; and generate a unit digital signal with a value of 1 and transmit the unit digital signal to the algorithmic logic controller if the input signal is greater than or equal to the reference signal.

In an embodiment, the algorithmic logic controller is a successive approximation algorithmic logic controller configured to implement a successive approximation algorithm.

In an embodiment, the successive approximation algorithmic logic controller includes a logic controller and a timing generator.

In an embodiment, the algorithmic logic controller is configured to trigger, in response to the unit digital signal and an external clock signal, the associated register to generate a trigger output within a single clock cycle; trigger a trigger adjacent to the associated register by using the trigger output to generate a next trigger output; and generate, if all the triggers are triggered, a target digital signal by using all the trigger outputs, and output the target digital signal.

In an embodiment, the algorithmic logic controller is configured to support synchronous logic or asynchronous logic.

In an embodiment, the comparator is a 1-bit analog-to-digital converter.

In an embodiment, the capacitor array includes multiple parallel-capacitor structures electrically connected to each other and a single intermediate capacitor. Each of the multiple parallel-capacitor structures includes a single cache capacitor and a bidirectional switch that are connected in series. The single intermediate capacitor is connected in series between the multiple parallel-capacitor structures, and quantities of the parallel-capacitor structures adjacent to the intermediate capacitor are equal to each other.

It can be seen from the above technical solutions that the present disclosure has the following advantages.

The analog-to-digital converter for partial discharge ultrasonic detection is provided according to the present disclosure, and includes a bootstrapped switch, a sampling capacitor array, a comparator and an algorithmic logic controller. The bootstrapped switch is connected to an input end of the comparator, and is turned on by using bootstrapping in response to a received sampling clock signal, and is configured to receive an input signal to be cached in the sampling capacitor array. The sampling capacitor array is connected to the input end of the comparator and is configured to cache the input signal. An output end of the comparator is connected to the algorithmic logic controller. The comparator is configured to compare the input signal with a reference signal bit by bit, generate a unit digital signal and transmit the unit digital signal to the algorithmic logic controller. The algorithmic logic controller is configured to trigger an associated register bit by bit in response to the unit digital signal, generate a target digital signal and output the target digital signal, thereby reducing the power consumption in the detection process of the partial discharge signal in the power device, and effectively reducing the cost.

### BRIEF DESCRIPTION OF THE DRAWINGS

In order to illustrate the embodiments of the present disclosure or the technical solutions in the conventional technology more clearly, the drawings to be used in the description of the embodiments or the conventional technology are briefly introduced hereinafter. Apparently, the drawings in the following description illustrate only some embodiments of the present disclosure. For those skilled in the art, other drawings can be obtained based on these drawings without creative effort.

FIG. 1 is a schematic structural diagram of an analog-to-digital converter for partial discharge ultrasonic detection according to an embodiment of the present disclosure;

FIG. 2 is a circuit diagram of a bootstrapped switch according to an embodiment of the present disclosure;

FIG. 3 is a schematic structural diagram of a double-tail current dynamic latch comparator according to an embodiment of the present disclosure;

FIG. 4 is a schematic circuit diagram of a timing generator according to an embodiment of the present disclosure;

FIG. 5 is a schematic diagram of a waveform outputted by a timing generator according to an embodiment of the present disclosure;

FIG. 6 is a schematic diagram of a logic structure of a successive approximation algorithmic logic controller according to an embodiment of the present disclosure; and FIG. 7 is a schematic circuit diagram of a capacitor array according to an embodiment of the present disclosure.

### DETAILED DESCRIPTION OF THE EMBODIMENTS

A low-power analog-to-digital converter for partial discharge detection is provided according to embodiments of the present disclosure, to solve the problem that the conventional ADC has large power consumption and high cost in the detection process of the partial discharge signal in the power device.

In order to make the objectives, features and advantages of the present disclosure more clear and understandable, the technical solutions in the embodiments of the present disclosure are clearly and completely described below in conjunction with the drawings of the embodiments of the present disclosure. Apparently, the following described embodiments are only some, but not all, of the embodiments of the present disclosure. All other embodiments obtained by those skilled in the art based on the embodiments of the present disclosure without creative efforts fall within the scope of protection of the present disclosure.

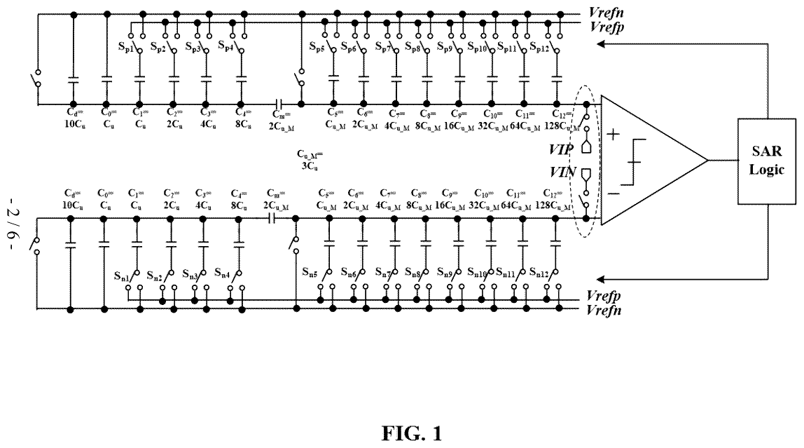

Reference is made to FIG. 1, which is a schematic structural diagram of an analog-to-digital converter for partial discharge ultrasound detection according to an embodiment of the present disclosure.

The analog-to-digital converter for partial discharge ultrasound detection according to the present disclosure includes a bootstrapped switch, a sampling capacitor array, a comparator and an algorithmic logic controller.

The bootstrapped switch is connected to an input end of the comparator. The bootstrapped switch is turned on by using bootstrapping in response to a received sampling clock signal, and is configured to receive an input signal to be cached in the sampling capacitor array.

The sampling capacitor array is connected to the input end of the comparator, and is configured to cache the input signal.

An output end of the comparator is connected to the algorithmic logic controller, the comparator is configured to compare the input signal with a reference signal bit by bit, generate a unit digital signal and transmit the unit digital signal to the algorithmic logic controller.

The algorithmic logic controller is configured to trigger an associated register bit by bit in response to the unit digital signal, generate a target digital signal and output the target digital signal.

In the embodiment of the present disclosure, a partial discharge input signal is amplified by a front-end amplifier circuit to a voltage less than or equal to a power supply voltage of the SARADC. The partial discharge input signal generates differential signals VIP and VIN after being amplified by the front-end amplifier circuit, and the differential signals VIP and VIN are inputted to a terminal VIP and a terminal VIN in FIG. 1, respectively. The inputted signals VIP and VIN are sampled in response to a clock at a high level, and the inputted signals VIP and VIN are quantified in response to a clock at a low level. The quantification process is as follows. A timing generator in SARLOGIC generates 13 comparison pulses, and the logic controller is controlled by these 13 clocks. In response to each clock, the logic controller modifies and feedbacks an input of the capacitor array based on an output of the comparator, achieving an effect of successive approximation. After one clock cycle, generated digital signals DN<11> to DN<0> may be used to quantify the input signals. The group of digital signals may be processed by a computer or other digital signal processing devices.

In an embodiment, the bootstrapped switch includes a third MOS transistor, a fourth MOS transistor, a fifth MOS transistor, a sixth MOS transistor, a seventh MOS transistor, an eighth MOS transistor, a ninth MOS transistor, a tenth MOS transistor and a digital power supply.

In response to the received sampling clock signal at a low level, the bootstrapped switch is configured to turn on the third MOS transistor and the eighth MOS transistor, gates of the fourth MOS transistor, the sixth MOS transistor, the ninth MOS transistor and the tenth MOS transistor are grounded through the seventh MOS transistor and the eighth MOS transistor, so that the fourth MOS transistor is turned on, and the sixth MOS transistor, the ninth MOS transistor and the tenth MOS transistor are turned off, pre-charging to the digital power supply.

In response to the received sampling clock signal at a high level, the fourth MOS transistor and the third MOS transistor are turned off, and the fifth MOS transistor is turned on, so that the bootstrapped switch is turned on to receive the input signal to be cached in the sampling capacitor array.

In this embodiment of the present disclosure, the bootstrapped switch is located in a dashed line box of the ADC structure in FIG. 1, and a circuit diagram of the bootstrapped switch in this embodiment is shown in FIG. 2, where SAMPLE represents a sampling clock signal and SAMPLEN represents an inversion signal of the sampling clock signal.

The operation principle of the bootstrapped switch includes a pre-charging process and a bootstrapping turn-on process.

In response to the sampling clock signal SAMPLE at a low level, the bootstrapped switch enters the pre-charging process. In this case, M3 and M8 are turned on, and gates of M4, M6, M9 and M10 are grounded through M7 and M8, where M4 is turned on, and M6, M9 and M10 are turned off, so that a voltage difference between an upper plate and a lower plate of a capacitor Cp is pre-charged to VDD and remains constant.

In response to the sampling clock signal SAMPLE at a high level, the bootstrapped switch enters the bootstrapping turn-on process. In this case, M3 and M4 are turned off and M5 is turned on, the upper plate and the lower plate of the capacitor Cp are connected to a gate and a source of M10, respectively, preventing an on-resistance of M10 from changing with the change of the input signal VIN.

It should be noted that since a voltage of the upper plate of the capacitor Cp may be greater than VDD, a phenomenon of forward biasing of a diode may occur at a source of M5 connected to the upper plate of the capacitor Cp. In order to avoid the phenomenon, the source of M5 is connected to a substrate of M5.

In an embodiment, the comparator is a double-tail current dynamic latch comparator.

In an embodiment, the comparator is a 1-bit analog-to-digital converter.

In an embodiment, the comparator is configured to compare the input signal with the reference signal bit by bit; generate a unit digital signal with a value of 0 and transmit the unit digital signal to the algorithmic logic controller if the input signal is less than the reference signal; and generate a unit digital signal with a value of 1 and transmit the unit digital signal to the algorithmic logic controller if the input signal is greater than or equal to the reference signal.

In an embodiment of the present disclosure, the comparator is one of basic modules in the analog-to-digital converter. The comparator outputs a binary digital signal by comparing the analog signal with the reference signal.

It should be noted that one comparator is one 1-bit analog-to-digital converter. In the embodiment of the present disclosure, the comparator may be classified as an open-loop comparator and a dynamic latch comparator. The dynamic latch comparator has characteristics such as low power consumption and a high speed, and thus is widely applied to the low-power analog-to-digital converter.

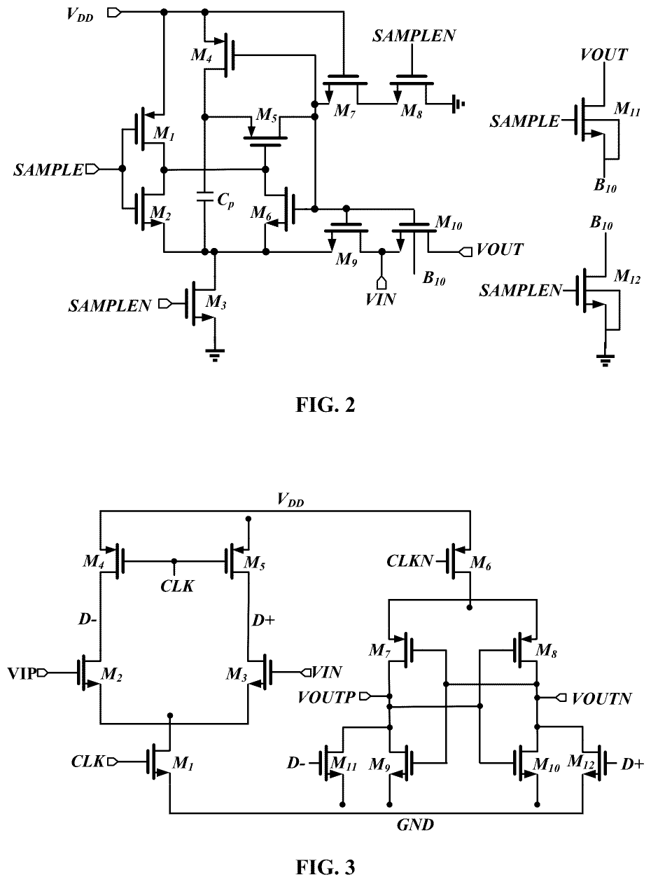

The double-tail current dynamic latch comparator is applied in this embodiment, and includes two parts of an input gain stage and an output latch as shown in FIG. 3.

In this embodiment, the dynamic latch comparator operates in the following process. Within a reset phase, in response to CLK at a low level, outputs D+ and D− of a first stage are pre-charged to VDD through M4 and M5, and output nodes VOUTP and VOUTN of a second stage are pulled down to ground. In this case, tail current transistors M1 and M6 at both stages are turned off. In response to CLK at a high level, the tail current transistor at the input stage is turned on, and the output nodes D+ and D− start to discharge. The discharge speeds are difference due to the different voltages of the differential inputs VIP and VIN. Therefore, a voltage difference between the nodes D+ and D− is transmitted to VOUTN and VOUTP through M11 and M12. Once a common-mode voltage of the nodes D+ and D− drops low enough until the nodes VOUTP and VOUTN fail to be clamped to ground, the latch enters a regeneration phase. Under the effect of positive feedback, a voltage of one end quickly increases to VDD and the other end is pulled down to ground, implementing the process of comparison.

In an embodiment, the algorithmic logic controller is a successive approximation algorithmic logic controller configured to implement a successive approximation algorithm.

In an embodiment, the successive approximation algorithmic logic controller includes a logic controller and a timing generator.

In an embodiment, the algorithmic logic controller is configured to trigger, in response to the unit digital signal and an external clock signal, the associated register to generate a trigger output within a single clock cycle; trigger a trigger adjacent to the register by using the trigger output to generate a next trigger output within the single clock cycle; and generate, if all the triggers are triggered, a target digital signal by using all the trigger outputs, and output the target digital signal.

In an embodiment of the present disclosure, the algorithmic logic controller supports synchronous logic or asynchronous logic.

The successive approximation algorithmic logic controller is configured to implement a successive approximation algorithm, and is a core module in the analog-to-digital converter. The controller may implement the successive approximation algorithm in a synchronous logic manner or an asynchronous logic manner.

In the synchronous logic, the circuit operates by using an external clock. The circuit operates once within each clock cycle. A 12-bit successive approximation analog-to-digital converter requires at least 12 clock cycles for quantifying the input signal, and further requires at least one clock cycle for sampling. Therefore, the analog-to-digital converter requires at least 13 clock cycles for implementing the digital output of one point. The synchronous logic has an advantage of intuitive logic, and each operation of the circuit is controlled by the external clock, thus strongly depending on the external clock. An analog-to-digital converter with a relatively high sampling rate requires a clock with at least 13 times a frequency of the input signal. Such the clock is difficult to be implemented, and thus the synchronous logic is limited by the sampling frequency of the analog-to digital-converter.

Compared with the synchronous logic, the asynchronous logic is less dependent on the clock, and a clock controlling the circuit to operate is generated internally by the logic circuit. In the asynchronous logic, a clock pulse is inputted from external, and the logic circuit generates an internal clock based on the clock pulse, so that the circuit performs an operation N times (using N-bit ADC) to implement the quantification of one point.

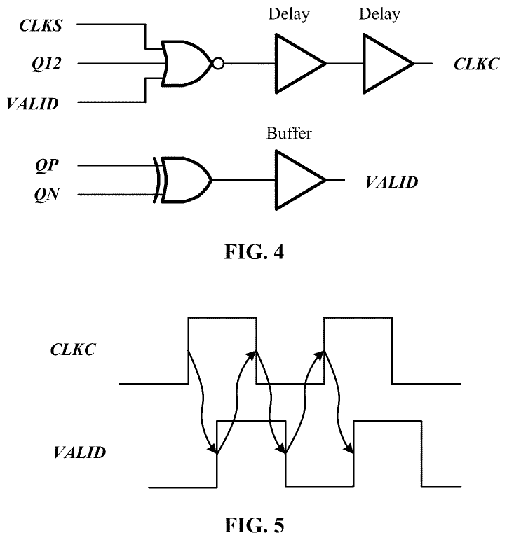

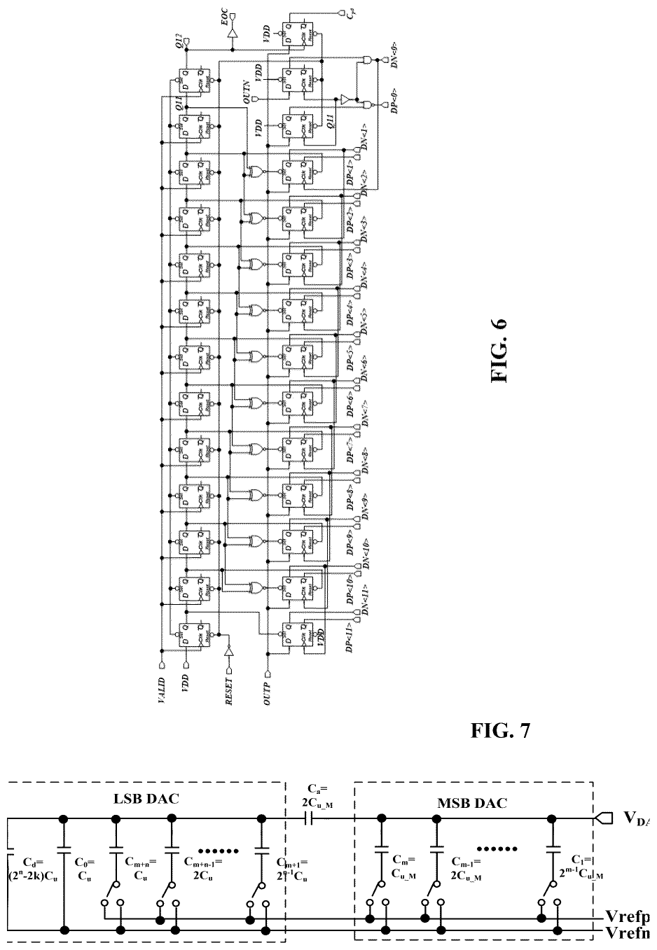

The successive approximation algorithmic logic controller includes two parts of a logic controller and a timing generator. The timing generator is as shown in FIG. 4, CLKS represents a sampling clock pulse, Q12 represents a last one clock outputted by the logic controller, CLKC represents a clock input of the comparator, QP represents a positive output of the comparator, and QN represents a negative output. The comparator starts to compare at a rising edge of the CLKC, and VALID is changed to a high level if the comparison ends. The rise of the VALID signal causes CLKC to fall, the fall of CLKC causes VALID to fall, and the fall of VALID causes CLKC to rise, so as to enter a next comparison cycle. The above operations are repeated to generate a closed loop. As a result, the timing generator outputs a waveform shown in FIG. 5. The VALID signal is used to trigger the internal clocks Q1 to Q12.

A logic structure of the successive approximation algorithmic logic controller in this embodiment is shown in FIG. 6. Before a sampling phase, the RESET signal resets an output of each trigger of a shifting register to 0. During the sampling, the VALID signal enables the first trigger of the shifting register to output the high level 1, and the output of other triggers remains at the low level 0. In this case, the control signal DN<11> is at the high level 1, and other control signals DN<0> to QN<10> are at the low level 0. During a conversion cycle, under the control of the VALID signal, outputs of a first row of triggers are sequentially changed to the high level 1, to cause outputs of a second row of triggers to be changed to the high level 1. In addition, the outputs of the first row of triggers and the outputs of the second row of triggers serve as the clock signals for previous-stage triggers. Therefore, DN<11> to DN<0> are reset, and then are triggered again at a next rising edge of the clock based on the output of the comparator, to obtain a successive approximate logic control signal.

Referring to FIG. 7, the capacitor array includes multiple parallel-capacitor structures electrically connected to each other and a single intermediate capacitor.

Each of the structures formed by capacitors in parallel includes a single cache capacitor and a bidirectional switch that are connected in series.

The intermediate capacitor is connected in series between the multiple parallel-capacitor structures, and quantities of the parallel-capacitor structures adjacent to the intermediate capacitor are equal to each other.

In an embodiment of the present disclosure, the capacitor array is configured to cache the received input signal, optimizing the power consumption and the area.

The analog-to-digital converter for partial discharge ultrasonic detection is provided according to the embodiments of the present disclosure, and includes a bootstrapped switch, a sampling capacitor array, a comparator and an algorithmic logic controller. The bootstrapped switch is connected to an input end of the comparator, and is turned on by using bootstrapping in response to a received sampling clock signal, and is configured to receive an input signal to be cached in the sampling capacitor array. The sampling capacitor array is connected to the input end of the comparator and is configured to cache the input signal. An output end of the comparator is connected to the algorithmic logic controller. The comparator is configured to compare the input signal with a reference signal bit by bit, generate a unit digital signal and transmit the unit digital signal to the algorithmic logic controller. The algorithmic logic controller is configured to trigger an associated register bit by bit in response to the unit digital signal, generate a target digital signal and output the target digital signal, thereby reducing the power consumption in the detection process of the partial discharge signal in the power device, and effectively reducing the cost.

Contents not described in detail in the specification of the present disclosure are deemed as well known to those skilled in the art.

In the embodiments according to the present disclosure, it should be understood that the disclosed analog-to-digital converter may be implemented in other manners. For example, the embodiments of the device described above are only illustrative. For example, the division of the units is only a division of a logical function, and there may be other division manners in actual implementation. For example, multiple units or components may be combined or integrated into another system, or some features may be omitted or not implemented. On the other hand, the coupling or direct coupling or communicative connection between each other shown or discussed may be implemented by some interfaces, the indirect coupling or the communicative connection between devices or units may be electrical, mechanical or other forms.

In summary, the above embodiments are only for illustrating the technical solutions of the present disclosure, and are not intended to limit the present disclosure. Although the present disclosure is illustrated in detail with reference to the embodiments described above, it should be understood by those skilled in the art that modification can be made to the technical solutions recited in the embodiments described above, or equivalent substitution can be made to a part of technical features of the technical solutions. The modifications and equivalent replacements will not make the nature of the corresponding technical solutions deviate from the spirit and scope of the technical solutions in the embodiments of the present disclosure.

1. An analog-to-digital converter for partial discharge ultrasonic detection, comprising
a bootstrapped switch;
a sampling capacitor array;
a comparator; and
an algorithmic logic controller, wherein
the bootstrapped switch is connected to an input end of the comparator and is turned on by using bootstrapping in response to a received sampling clock signal, and is configured to receive an input signal to be cached in the sampling capacitor array;
the sampling capacitor array is connected to the input end of the comparator and is configured to cache the input signal;
an output end of the comparator is connected to the algorithmic logic controller, and the comparator is configured to compare the input signal with a reference signal bit by bit, generate a unit digital signal, and transmit the unit digital signal to the algorithmic logic controller; and
the algorithmic logic controller is configured to trigger an associated register bit by bit in response to the unit digital signal, generate a target digital signal, and output the target digital signal.

2. The analog-to-digital converter for partial discharge ultrasonic detection according to claim 1, wherein the bootstrapped switch comprises a third MOS transistor, a fourth MOS transistor, a fifth MOS transistor, a sixth MOS transistor, a seventh MOS transistor, an eighth MOS transistor, a ninth MOS transistor, a tenth MOS transistor and a digital power supply, wherein
in response to the received sampling clock signal at a low level, the bootstrapped switch is configured to turn on the third MOS transistor and the eighth MOS transistor, gates of the fourth MOS transistor, the sixth MOS transistor, the ninth MOS transistor and the tenth MOS transistor are grounded through the seventh MOS transistor and the eighth MOS transistor, wherein the fourth MOS transistor is turned on, and the sixth MOS transistor, the ninth MOS transistor and the tenth MOS transistor are turned off, and the digital power supply pre-charges a capacitor; and
in response to the received sampling clock signal at a high level, the fourth MOS transistor and the third MOS transistor are turned off, the fifth MOS transistor is turned on, wherein the bootstrapped switch is turned on to receive the input signal to be cached in the sampling capacitor array.

3. The analog-to-digital converter for partial discharge ultrasonic detection according to claim 1, wherein the comparator is a double-tail current dynamic latch comparator.

4. The analog-to-digital converter for partial discharge ultrasonic detection according to claim 1, wherein the comparator is configured to:
compare the input signal with the reference signal bit by bit;
generate a unit digital signal with a value of 0 and transmit the unit digital signal to the algorithmic logic controller if the input signal is less than the reference signal; and
generate a unit digital signal with a value of 1 and transmit the unit digital signal to the algorithmic logic controller if the input signal is greater than or equal to the reference signal.

5. The analog-to-digital converter for partial discharge ultrasonic detection according to claim 1, wherein the algorithmic logic controller is a successive approximation algorithmic logic controller configured to implement a successive approximation algorithm.

6. The analog-to-digital converter for partial discharge ultrasonic detection according to claim 5, wherein the successive approximation algorithmic logic controller comprises a logic controller and a timing generator.

7. The analog-to-digital converter for partial discharge ultrasonic detection according to claim 1, wherein the algorithmic logic controller is configured to:
trigger, in response to the unit digital signal and an external clock signal, the associated register to generate a trigger output within a single clock cycle;
trigger a trigger adjacent to the associated register by using the trigger output to generate a next trigger output within the single clock cycle; and
generate, if all the triggers are triggered, a target digital signal by using all the trigger outputs, and output the target digital signal.

8. The analog-to-digital converter for partial discharge ultrasonic detection according to claim 1, wherein the algorithmic logic controller is configured to support synchronous logic or asynchronous logic.

9. The analog-to-digital converter for partial discharge ultrasonic detection according to claim 1, wherein the comparator is a 1-bit analog-to-digital converter.

10. The analog-to-digital converter for partial discharge ultrasonic detection according to claim 1, wherein the capacitor array comprises a plurality of parallel-capacitor structures electrically connected to each other and a single intermediate capacitor; wherein each of the plurality of parallel-capacitor structures comprises a single cache capacitor and a bidirectional switch that are connected in series; and
the single intermediate capacitor is connected in series between the plurality of parallel-capacitor structures.
